(19) United States
(12) Patent Application Publication
(10) Pub. No.: US 2015/0034788 A1
(43) Pub. Date: Feb. 5, 2015

(54) Rotatable Frame For a Lithographic Apparatus

(71) Applicant: ASML Netherlands B.V., Veldhoven (NL)

(72) Inventors: Arno Jan Bleeker, Westerhoven (NL); Thomas Josephus Maria Castenmill, Eindhoven (NL); Pieter Willem Herman De Jager, Middelbeers (NL); Heine Melle Mulder, Veldhoven (NL); Koen Jacobus Johannes Maria Zaal, Eindhoven (NL); Theodorus Petrus Maria Cadee, Asten (NL); Danny Maria Hubertus Philips, Son en Breugel (NL); Ruud Antonius Catharina Maria Beere, Roggel (NL); Roger Anton Marie Timmermans, Nederweert (NL)

(21) Appl. No.: 14/382,228

(22) PCT Filed: Jan. 30, 2013
(86) PCT No.: PCT/EP2013/051800

§ 371 Date: Aug. 29, 2014

Related U.S. Application Data
(60) Provisional application No. 61/622,922, filed on Apr. 11, 2012.

(51) Int. Cl. G03F 7/20

(52) U.S. Cl. CPC G03F 7/20
USPC 248/349.1

(57) ABSTRACT

A projection system, configured to project a radiation beam onto a target, includes a rotatable frame (8) configured to rotate about an axis defining a tangential direction and a radial direction, wherein the rotatable frame holds a lens configured to focus the radiation beam in only the tangential or radial direction; and a stationary part comprising a substantially stationary lens configured to focus the radiation beam in only the other of the tangential or radial direction. Provisions are made to prevent moments to be exerted on the lens held by the rotatable frame.

### CROSS-REFERENCE TO RELATED APPLICATIONS

This application claims the benefit of U.S. provisional application 61/622,922, which was filed on Apr. 11, 2012 and which is incorporated herein in its entirety by reference.

### FIELD

The present invention relates to a rotatable frame, a lithographic apparatus, a projection system, a method for focusing radiation and a device manufacturing method.

### BACKGROUND

A lithographic or exposure apparatus is a machine that applies a desired pattern onto a substrate or part of a substrate. The apparatus may be used, for example, in the manufacture of integrated circuits (ICs), flat panel displays and other devices or structures having fine features. In a conventional lithographic or exposure apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, arrays of self-emissive contrast devices and the like. A programmable patterning device could also be formed from an electro-optical deflector, configured for example to move spots of radiation projected onto a target (e.g., the substrate) or to intermittently direct a radiation beam away from the target (e.g., the substrate), for example to a radiation beam absorber. In either such arrangement, the radiation beam may be continuous.

### SUMMARY

A maskless lithographic or exposure apparatus may be provided with, for example, an optical column capable of creating a pattern on a target portion of a substrate. The optical column may be provided with a self emissive contrast device configured to emit a beam and a projection system configured to project at least a portion of the beam onto a target. The apparatus may be provided with an actuator to move the optical column or a part thereof with respect to the substrate. By, for example, movement of the optical column or a part thereof, the beam may be moved with respect to the substrate. By switching “on” or “off” the self-emissive contrast device during the movement of the beam, a pattern on the substrate may be created.

It is desirable, for example, to improve the accuracy of printing radiation beams onto a target (e.g., of a substrate).

According to an embodiment of the invention, there is provided a rotatable frame, for use in a lithographic apparatus, configured to rotate about an axis, the rotatable frame comprising: a shaft; and a flange extending radially outwards at an angle relative to the axis and configured to hold a lens, wherein the flange is positioned between an upper section and a lower section of the shaft, wherein the upper section and the lower section are configured such that during rotation a moment exerted on the flange by the upper section opposes and substantially equals a moment exerted on the flange by the lower section.

According to an embodiment of the invention, there is provided a rotatable frame, for use in a lithographic apparatus, configured to rotate about an axis, the rotatable frame comprising: a shaft; and a flange extending radially outwards at an angle relative to the axis and configured to hold a lens, wherein during rotation a section of the shaft on one side, in the axial direction, of the flange exerts substantially no moment on the flange.

According to an embodiment of the invention, there is provided a rotatable frame, for use in a lithographic apparatus, configured to rotate about an axis, the rotatable frame comprising: a shaft; and a flange extending radially outwards at an angle relative to the axis and configured to hold a lens, wherein the flange comprises a recess or a protruding rim on a surface of the flange that faces the middle, in the axial direction, of the shaft.

According to an embodiment of the invention, there is provided a rotatable frame, for use in a lithographic apparatus, configured to rotate about an axis, the rotatable frame comprising: a shaft; and a flange extending radially outwards at an angle relative to the axis and configured to hold a lens, wherein the flange is connected to the shaft by a connector that is more flexible that the flange.

According to an embodiment of the invention, there is provided a projection system, configured to project a radiation beam onto a target, comprising: a rotatable frame configured to rotate about an axis defining a tangential direction and a radial direction, wherein the rotatable frame holds a lens configured to focus the radiation beam in only the tangential or radial direction; and a stationary part comprising a substantially stationary lens configured to focus the radiation beam in only the other of the tangential or radial direction.

According to an embodiment of the invention, there is provided a method of focusing a radiation beam onto a target using a lithographic apparatus, the method comprising: focusing the radiation beam in only a tangential direction or a radial direction of a rotatable frame configured to rotate about an axis with a lens held by the rotatable frame; and focusing the radiation beam in only the other of the tangential direction or the radial direction by a substantially stationary lens.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a part of a lithographic or exposure apparatus according to an embodiment of the invention;

FIG. 2 depicts a top view of a part of the apparatus of FIG. 1 according to an embodiment of the invention;

FIG. 3 depicts a highly schematic, perspective view of a part of a lithographic or exposure apparatus according to an embodiment of the invention;

FIG. 4 depicts a schematic top view of projections by the apparatus according to FIG. 3 onto a target according to an embodiment of the invention;

FIG. 5 depicts in cross-section, a part of an embodiment of the invention;

FIG. 6 depicts schematically a rotatable frame according to an embodiment of the invention;

FIG. 7 depicts schematically part of a rotatable frame according to an embodiment of the invention;

FIG. 8 depicts schematically part of a rotatable frame according to an embodiment of the invention;

FIG. 9 depicts schematically part of a rotatable frame according to an embodiment of the invention;

FIG. 10 depicts schematically part of a rotatable frame according to an embodiment of the invention;

FIG. 11 depicts schematically part of a rotatable frame according to an embodiment of the invention;

FIG. 12 depicts schematically part of a rotatable frame according to an embodiment of the invention;

FIG. 13 depicts schematically part of a projection system according to an embodiment of the invention;

FIG. 14 depicts schematically part of a projection system according to an embodiment of the invention;

FIG. 15 depicts schematically part of a projection system according to an embodiment of the invention;

FIG. 16 depicts schematically part of a projection system according to an embodiment of the invention;

FIG. 17 depicts schematically part of a projection system according to an embodiment of the invention;

FIG. 18 depicts schematically part of a projection system according to an embodiment of the invention;

FIG. 19 depicts schematically part of a projection system according to an embodiment of the invention; and

FIG. 20 depicts schematically part of a rotatable frame according to an embodiment of the invention.

### DETAILED DESCRIPTION

An embodiment of the present invention relates to an apparatus that may include a programmable patterning device that may, for example, be comprised of an array or arrays of self-emissive contrast devices. Further information regarding such an apparatus may be found in PCT patent application publication no. WO 2010/032224 A2, U.S. patent application publication no. US 2011-0188016, U.S. patent application no. U.S. 61/473,636 and U.S. patent application No. 61/524,190 which are hereby incorporated by reference in their entireties. An embodiment of the present invention, however, may be used with any form of programmable patterning device including, for example, those discussed above.

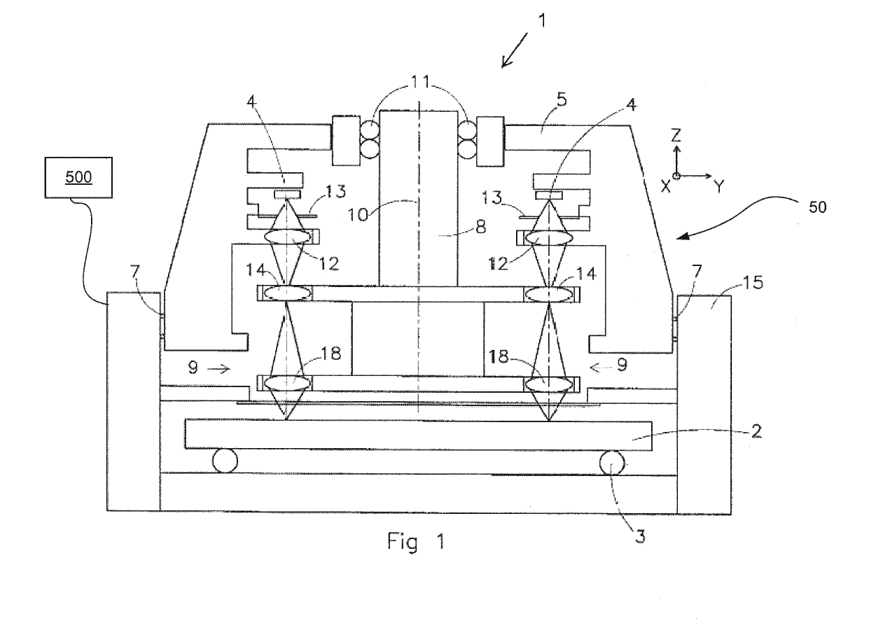

FIG. 1 schematically depicts a schematic cross-sectional side view of a part of a lithographic or exposure apparatus. In this embodiment, the apparatus has individually controllable elements substantially stationary in the X-Y plane as discussed further below although it need not be the case. The apparatus 1 comprises a substrate table 2 to hold a substrate, and a positioning device 3 to move the substrate table 2 in up to 6 degrees of freedom. The substrate may be a resist-coated substrate. In an embodiment, the substrate is a wafer. In an embodiment, the substrate is a polygonal (e.g. rectangular) substrate. In an embodiment, the substrate is a glass plate. In an embodiment, the substrate is a plastic substrate. In an embodiment, the substrate is a foil. In an embodiment, the apparatus is suitable for roll-to-roll manufacturing.

The apparatus 1 further comprises a plurality of individually controllable self-emissive contrast devices 4 configured to emit a plurality of beams. In an embodiment, the self-emissive contrast device 4 is a radiation emitter, e.g. a radiation emitting diode, such as a light emitting diode (LED), an organic LED (OLED), a polymer LED (PLED), a fiber laser or a laser diode (e.g., a solid state laser diode). In an embodiment, each of the individually controllable elements 4 is a blue-violet laser diode (e.g., Sanyo model no. DL-3146-151). Such diodes may be supplied by companies such as Sanyo, Nichia, Osram, and Nitride. In an embodiment, the diode emits UV radiation, e.g., having a wavelength of about 365 nm or about 405 nm. In an embodiment, the diode can provide an output power selected from the range of 0.5-250 mW, and optionally an output power of at least 50 mW. In an embodiment the output power of a device 60, that may comprise a self-emissive contrast device 4, is greater than 250 mW. In an embodiment, the size of laser diode (naked die) is selected from the range of 100-800 micrometers. In an embodiment, the laser diode has an emission area selected from the range of 0.5-5 micrometers². In an embodiment, the laser diode has a divergence angle selected from the range of 5-44 degrees. In an embodiment, the diodes have a configuration (e.g., emission area, divergence angle, output power, etc.) to provide a total brightness more than or equal to about 6.4×10⁸ W/(m²·sr).

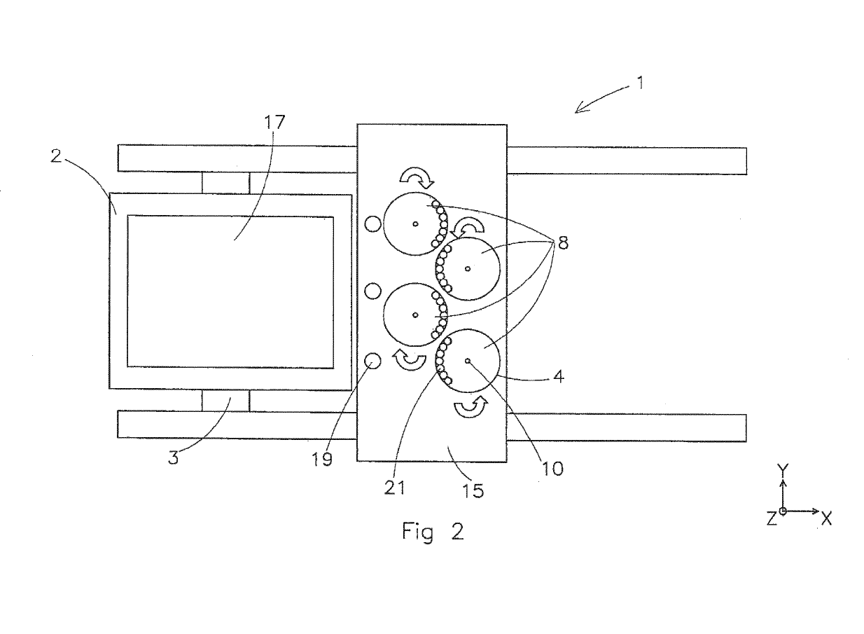

The self-emissive contrast devices 4 are arranged on a frame 5 and may extend along the Y-direction and/or the X direction. While one frame 5 is shown, the apparatus may have a plurality of frames 5 as shown in FIG. 2. Further arranged on the frame 5 is lens 12. Frame 5 and thus self-emissive contrast device 4 and lens 12 are substantially stationary in the X-Y plane. Frame 5, self-emissive contrast device 4 and lens 12 may be moved in the Z-direction by actuator 7. Alternatively or additionally, lens 12 may be moved in the Z-direction by an actuator related to this particular lens. Optionally, each lens 12 may be provided with an actuator.

The self-emissive contrast device 4 may be configured to emit a beam and the projection system 12, 14 and 18 may be configured to project the beam onto a target portion of, e.g., the substrate. The self-emissive contrast device 4 and the projection system form an optical column. The apparatus 1 may comprise an actuator (e.g. motor 11) to move the optical column or a part thereof with respect to the substrate. Frame 8 with arranged thereon field lens 14 and imaging lens 18 may be rotatable with the actuator. A combination of field lens 14 and imaging lens 18 forms movable optics 9. In use, the frame 8 rotates about its own axis 10, for example, in the directions shown by the arrows in FIG. 2. The frame 8 is rotated about the axis 10 using an actuator (e.g. motor) 11. Further, the frame 8 may be moved in a Z direction by motor 7 so that the movable optics 9 may be displaced relative to the substrate table 2.

An aperture structure 13 having an aperture therein may be located above lens 12 between the lens 12 and the self-emissive contrast device 4. The aperture structure 13 can limit diffraction effects of the lens 12, the associated self-emissive contrast device 4 or of an adjacent lens 12 and a self-emissive contrast device 4.

The depicted apparatus may be used by rotating the frame 8 and simultaneously moving the substrate on the substrate table 2 underneath the optical column. The self-emissive contrast device 4 can emit a beam through the lenses 12, 14, and 18 when the lenses are substantially aligned with each other. By moving the lenses 14 and 18, the image of the beam on, e.g., the substrate is scanned over a portion of the substrate. By simultaneously moving the substrate on the substrate table 2 underneath the optical column, the portion of the substrate 17, which is subjected to an image of the self-emissive contrast device 4 is also moving. By switching the self-emissive contrast device 4 “on” and “off” (e.g., having no output or output below a threshold when it is “off” and having an output above a threshold when it is “on”) at high speed under control of a controller, controlling the rotation of the optical column or part thereof, controlling the intensity of the self-emissive contrast device 4, and controlling the speed of the substrate, a desired pattern can be imaged in the resist layer on the substrate.

A controller 500 shown in FIG. 1 controls the overall operations of the lithographic apparatus and in particular performs a process described herein. Controller 500 can be embodied as a suitably-programmed general purpose computer comprising a central processing unit and volatile and/or non-volatile storage. Optionally, the computer may include one or more input and output devices such as a keyboard and screen, one or more network connections and/or one or more interfaces to the various parts of the lithographic apparatus. It will be appreciated that a one-to-one relationship between controlling computer and lithographic apparatus is not necessary. In an embodiment, one computer can control multiple lithographic apparatuses. In an embodiment, multiple networked computers can be used to control one lithographic apparatus. The controller 500 may be configured to control one or more associated process devices and/or substrate handling devices in a lithocell or cluster of which the lithographic apparatus forms a part. The controller 500 can be configured to be subordinate to a supervisory control system of a lithocell or cluster and/or an overall control system of a fab.

FIG. 2 depicts a schematic top view of the apparatus of FIG. 1 having self-emissive contrast devices 4. Like the apparatus 1 shown in FIG. 1, the apparatus 1 comprises a substrate table 2 to hold a substrate 17, a positioning device 3 to move the substrate table 2 in up to 6 degrees of freedom, an alignment/level sensor 19 to determine alignment between the self-emissive contrast device 4 and the substrate 17, and to determine whether the substrate 17 is at level with respect to the projection of the self-emissive contrast device 4. As depicted the substrate 17 has a rectangular shape, however also or alternatively round substrates may be processed.

The self-emissive contrast device 4 is arranged on a frame 15. The self-emissive contrast device 4 may be a radiation emitting diode, e.g., a laser diode, for instance a blue-violet laser diode. As shown in FIG. 2, the self-emissive contrast devices 4 may be arranged into an array 21 extending in the X-Y plane.

The array 21 may be an elongate line. In an embodiment, the array 21 may be a single dimensional array of self-emissive contrast devices 4. In an embodiment, the array 21 may be a two dimensional array of self-emissive contrast device 4.

A rotating frame 8 may be provided which may be rotating in a direction depicted by the arrow. The rotating frame may be provided with lenses 14, 18 (show in FIG. 1) to provide an image of each of the self-emissive contrast devices 4. The apparatus may be provided with an actuator to rotate the optical column comprising the frame 8 and the lenses 14, 18 with respect to the substrate.

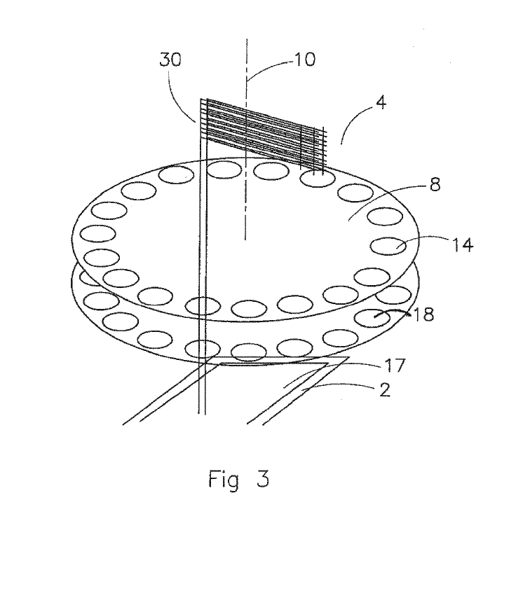

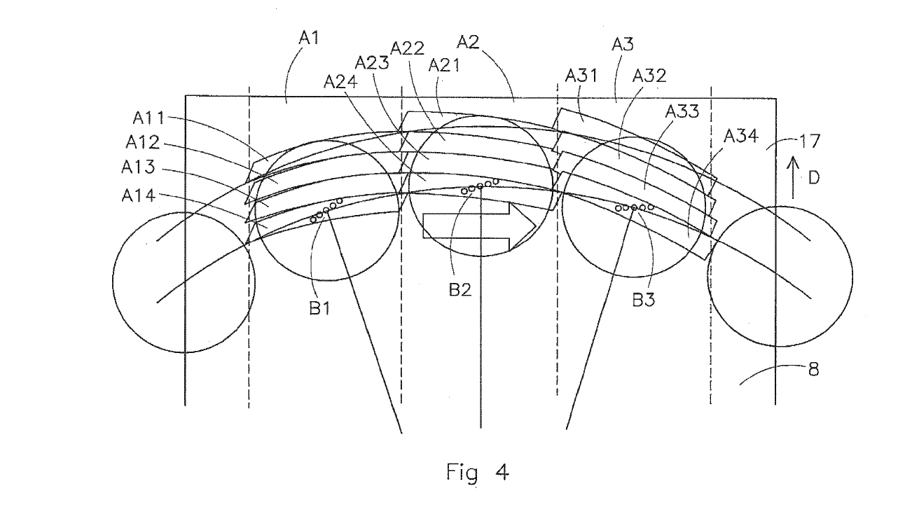

FIG. 3 depicts a highly schematic, perspective view of the rotating frame 8 provided with lenses 14, 18 at its perimeter. A plurality of beams, in this example 10 beams, are incident onto one of the lenses and projected onto a target portion of, e.g., the substrate 17 held by the substrate table 2. In an embodiment, the plurality of beams is arranged in a straight line. The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the surface of the substrate 17, as will be explained in more detail with reference to FIG. 4. In an embodiment, each beam is generated by a respective source, i.e. a self-emissive contrast device, e.g. a laser diode (not shown in FIG. 3). In the arrangement depicted in FIG. 3, the beams are deflected and brought together by a segmented mirror 30 in order to reduce a distance between the beams, to thereby enable a larger number of beams to be projected through the same lens and to achieve resolution requirements to be discussed below.

As the rotatable frame rotates, the beams are incident on successive lenses. Each time a lens is irradiated by the beams, the places where the beam is incident on a surface of the lens, moves. Since the beams are projected on the target differently (with e.g. a different deflection) depending on the place of incidence of the beams on the lens, the beams (when reaching the target) will make a scanning movement with each passage of a following lens. This principle is further explained with reference to FIG. 4.

FIG. 4 depicts a highly schematic top view of a part of the rotatable frame 8. A first set of beams is denoted by B1. A second set of beams is denoted by B2. A third set of beams is denoted by B3. Each set of beams is projected through a respective lens set 14, 18 of the rotatable frame 8. As the rotatable frame 8 rotates, the beams B1 are projected onto the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D. The direction D may be along the X axis as depicted in FIG. 2. The direction D may be substantially perpendicular to the scanning direction of the beams in the areas A14, A24, A34.

As a result of the movement in direction D by a second actuator (e.g. a movement of the substrate table by a corresponding substrate table motor), successive scans of the beams when being projected by successive lenses of the rotatable frame 8, are projected so as to substantially abut each other. This results in substantially abutting areas A11, A12, A13, A14 (areas A11, A12, A13 being previously scanned and A14 being currently scanned as shown in FIG. 4) for each successive scan of beams B1. Areas A21, A22, A23 and A24 (areas A21, A22, A23 being previously scanned and A24 being currently scanned as shown in FIG. 4) are for beams B2. Areas A31, A32, A33 and A34 (areas A31, A32, A33 being previously scanned and A34 being currently scanned as shown in FIG. 4) are for beams B3. Thereby, the areas A1, A2 and A3 of the substrate surface may be covered with a movement of the substrate in the direction D while rotating the rotatable frame 8.

The projecting of multiple beams through a same lens allows processing of a whole substrate in a shorter timeframe (at a same rotating speed of the rotatable frame 8). This is because for each passing of a lens, a plurality of beams scan the substrate 17 with each lens. This allows increased displacement in the direction D for successive scans. Viewed differently, for a given processing time, the rotating speed of the rotatable frame may be reduced when multiple beams are projected onto the substrate via a same lens. This possibly reduces effects such as deformation of the rotatable frame, wear, vibrations, turbulence, etc. due to high rotating speed.

In an embodiment, the plurality of beams is arranged at an angle to the tangent of the rotation of the lenses 14, 18 as shown in FIG. 4. In an embodiment, the plurality of beams is arranged such that each beam overlaps or abuts a scanning path of an adjacent beam.

A further effect of the aspect that multiple beams are projected at a time by the same lens may be found in relaxation of tolerances. Due to tolerances of the lenses (positioning, optical projection, etc), positions of successive areas A11, A12, A13, A14 (and/or of areas A21, A22, A23 and A24 and/or of areas A31, A32, A33 and A34) may show some degree of positioning inaccuracy in respect of each other. Therefore, some degree of overlap between successive areas A11, A12, A13, A14 may be required. In case of for example 10% of one beam as overlap, a processing speed would thereby be reduced by a same factor of 10% in case of a single beam at a time through a same lens. In a situation where there are 5 or more beams projected through a same lens at a time, the same overlap of 10% (similarly referring to one beam example above) would be provided for every 5 or more projected lines, hence reducing a total overlap by a factor of approximately 5 or more to 2% or less, thereby having a significantly lower effect on overall processing speed. Similarly, projecting at least 10 beams may reduce a total overlap by approximately a factor of 10. Thus, effects of tolerances on processing time of a substrate may be reduced by the feature that multiple beams are projected at a time by the same lens. In addition or alternatively, more overlap (hence a larger tolerance band) may be allowed, as the effects thereof on processing are low given that multiple beams are projected at a time by the same lens.

Alternatively or in addition to projecting multiple beams via a same lens at a time, interlacing techniques could be used, which however may require a comparably more stringent matching between the lenses. Thus, the at least two beams projected onto the substrate at a time via the same one of the lenses have a mutual spacing, and the apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. The spacing may be further reduced by providing a segmented mirror 30 in the optical path, each segment to reflect a respective one of the beams, the segments being arranged so as to reduce a spacing between the beams as reflected by the mirrors in respect of a spacing between the beams as incident on the mirrors. Such effect may also be achieved by a plurality of optical fibers. Each of the beams is incident on a respective one of the fibers. The fibers are arranged so as to reduce a spacing between the beams along an optical path. As a result the beam spacing downstream of the optical fibers is less than the beam spacing upstream of the optical fibers.

Further, such effect may be achieved using an integrated optical waveguide circuit having a plurality of inputs, each for receiving a respective one of the beams. The integrated optical waveguide circuit is arranged so as to reduce along an optical path a spacing between the beams downstream of the integrated optical waveguide circuit in respect of a spacing between the beams upstream of the integrated optical waveguide circuit.

A system may be provided for controlling the focus of an image projected onto a substrate. The arrangement may be provided to adjust the focus of the image projected by part or all of an optical column in an arrangement as discussed above.

In an embodiment the projection system projects the at least one radiation beam onto a substrate formed from a layer of material above the substrate 17 on which a device is to be formed so as to cause local deposition of droplets of the material (e.g. metal) by a laser induced material transfer.

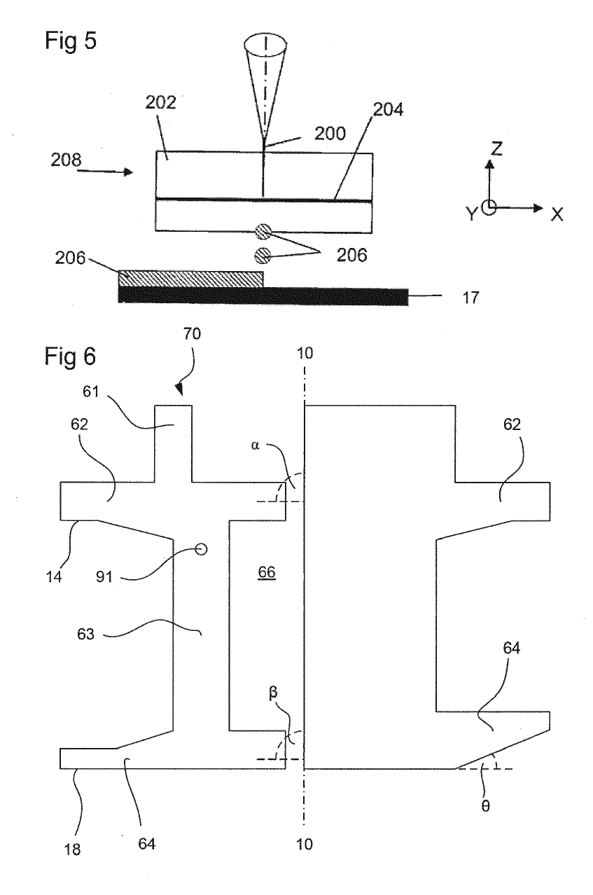

Referring to FIG. 5, the physical mechanism of laser induced material transfer is depicted. In an embodiment, a radiation beam 200 is focused through a substantially transparent material 202 (e.g., glass) at an intensity below the plasma breakdown of the material 202. Surface heat absorption occurs on a substrate formed from a donor material layer 204 (e.g., a metal film) overlying the material 202. The heat absorption causes melting of the donor material 204. Further, the heating causes an induced pressure gradient in a forward direction leading to forward acceleration of a donor material droplet 206 from the donor material layer 204 and thus from the donor structure (e.g., plate) 208. Thus, the donor material droplet 206 is released from the donor material layer 204 and is moved (with or without the aid of gravity) toward and onto the substrate 17 on which a device is to be formed. By pointing the beam 200 on the appropriate position on the donor plate 208, a donor material pattern can be deposited on the substrate 17. In an embodiment, the beam is focused on the donor material layer 204.

In an embodiment, one or more short pulses are used to cause the transfer of the donor material. In an embodiment, the pulses may be a few picoseconds or femto-seconds long to obtain quasi one dimensional forward heat and mass transfer of molten material. Such short pulses facilitate little to no lateral heat flow in the material layer 204 and thus little or no thermal load on the donor structure 208. The short pulses enable rapid melting and forward acceleration of the material (e.g., vaporized material, such as metal, would lose its forward directionality leading to a splattering deposition). The short pulses enable heating of the material to just above the heating temperature but below the vaporization temperature. For example, for aluminum, a temperature of about 900 to 1000 degrees Celsius is desirable.

In an embodiment, through the use of a laser pulse, an amount of material (e.g., metal) is transferred from the donor structure 208 to the substrate 17 in the form of 100-1000 nm droplets. In an embodiment, the donor material comprises or consists essentially of a metal. In an embodiment, the metal is aluminum. In an embodiment, the material layer 204 is in the form a film. In an embodiment, the film is attached to another body or layer. As discussed above, the body or layer may be a glass.

FIG. 1 depicts an embodiment of the invention. The lithographic apparatus 1 comprises a projection system 50 that comprises a stationary part and a moving part. The projection system may comprise lenses 12, 14 and 18 as depicted in FIG. 1, for example. The projection system 50 is configured to project a plurality of radiation beams onto locations on a substrate 17. The locations are selected based on a pattern. The pattern is to be formed on the substrate 17. In an embodiment the pattern is formed in a layer of photoresist material. In an embodiment the pattern is formed in a layer of donor material, which subsequently forms a corresponding pattern in a layer of a device.

FIG. 1 depicts a frame 8 that rotates about the axis 10 during use of the apparatus 1. The frame 8 can deform as a result of its rotation or translation. For example, one or more parts of the frame 8 can expand in the radial direction as a result of the rotation. One or more other pieces of rotating or moving equipment in the apparatus 1 may also deform as a result of its respective rotation or other movement.

The frame 8 of FIG. 1 may be configured to hold at least one field lens 14 and at least one imaging lens 18. It is desirable for these lenses to be positioned accurately with respect to each other and with respect to the apparatus 1 in order to improve the imaging accuracy of the apparatus 1.

In particular, in one printing method in which the apparatus 1 can be used, each swipe of the radiation spot brush generates a pattern of lines instead of a continuous band. A subsequent swipe of the radiation spot brush is timed such that it fills in (part of) the spaces between lines written in a previous swipe(s). Repeating this action and properly timing the switching “on” and “off” of the self-emissive contrast devices 4 and movement of the target (e.g., substrate 17) results in a continuously filled surface on the substrate 17. This printing method is called interlaced printing.

In interlaced printing, each line should be placed (i.e. printed) with respect to its neighbor with high precision. In this case, high precision means to within 100 nm, for example. The position at which each line is printed on the target is directly related to the positioning of the lenses 14, 18 on the frame 8. As such, these lenses 14, 18 are desirably placed on the frame 8 with an accuracy of within, e.g., 100 nm. Mechanically this is extremely challenging, in particular due to the centripetal forces exerted on the lenses 14, 18 during operation, in addition to manufacturing tolerances.

It is desirable, for example, to provide a apparatus 1 in which the lenses 14, 18 are positioned more accurately with respect to each other and with respect to the apparatus 1 during movement of the frame 8. It is desirable to reduce the constraint as to how accurately the lenses 14, 18 are positioned with respect to each other and with respect to the apparatus 1.

FIG. 6 depicts a frame 8 according to an embodiment of the present invention. The section of FIG. 6 to the left of the axis 10 depicts a cross-sectional view of the frame 8 at rest. The section of FIG. 6 to the right of the axis 10 depicts an external view of the frame 8 during rotation.

In an embodiment the frame 8 comprises a shaft 70 and a flange 62. The flange 62 extends radially outwards at an angle α relative to the axis 10. The flange 62 is configured to hold at least one lens 14, 18. The at least one lens may be, for example, a field lens 14 or an imaging lens 18.

In an embodiment the frame 8 is configured such that the angle α at which the flange extends is substantially constant over a continuous range of rotational speeds. Here, substantially constant means that the angle α changes by at most 1 mrad, for example. The direction of rotation is irrelevant.

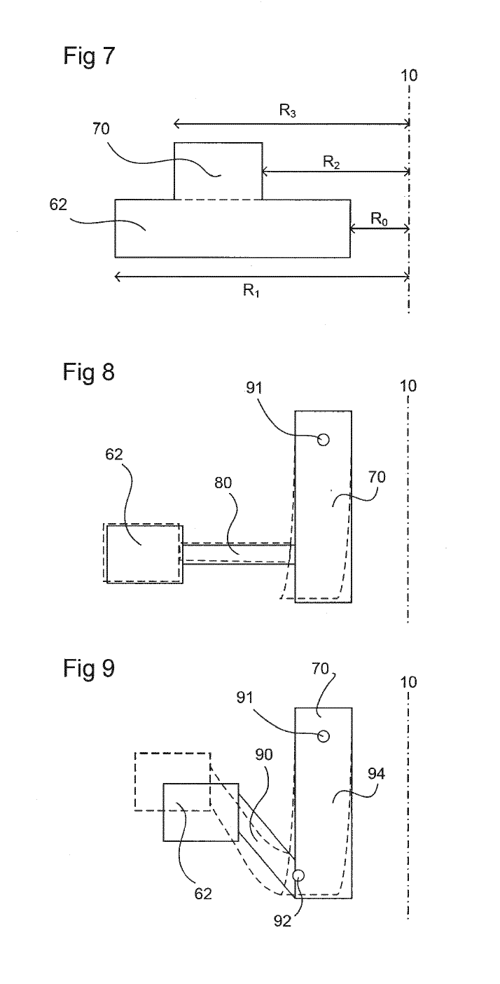

As mentioned above, rotating equipment expands in the radial direction as a result of rotation. The amount of expansion is determined, in part, by the rotational speed and the radius of the piece of equipment. As shown in FIG. 6, the radius of the frame 8 varies over the height (in the Z direction) of the frame 8. For example, the flange 62 has an outer radius R₁ that is greater than an outer radius R₃ of the shaft 70 (see FIG. 7).

As a result, some sections of the frame 8 are subject to a greater expansion stress than other sections of the frame 8. The difference in expansion stress across the frame 8 introduces a deflection, or tilt, of the frame 8. In the case of the flange 62, the deflection can result in the angle α at which the flange 62 extends varying as the rotational speed of the frame 8 varies. This is depicted schematically in FIG. 6.

In the right hand section of FIG. 6, the flange 64 undergoes a deflection when the frame 8 rotates. The left hand side of FIG. 6 shows that at rest (i.e. a rotation speed of 0), the flange 64 extends at an angle β with respect to the axis 10 wherein the angle β is about 90 degrees. The right hand side of FIG. 6 shows that when the frame 8 rotates, the frame 8 undergoes a deflection such that the flange 64 extends at an angle of 90 degrees minus θ with respect the axis 10. Such a deflection will undesirably change the position at which the lens 18 held by the flange 64 focuses a radiation beam onto the target.

By configuring the frame 8 such that the angle α at which the flange 62 extends is substantially constant over a continuous range of rotational speeds, deflection of the frame 8 is reduced. As a result, the focusing of radiation beams performed by the at least one lens 14, 18 held by the flange 62 is more consistent as the rotational speed of the frame 8 varies.

Rotation of the frame 8 may cause the radius of the frame 8 at a particular point to change by from about 50 μm to about 100 μm at a rotational speed of about 80 Hz. These values are for a frame 8 made from steel. In general, the greater the rotational speed of the frame 8, the greater the expansion of the radius of the frame 8. For example, if the rotational speed is about 140 Hz, then the change in radius of a particular point on the frame 8 may be of the order of from about 150 μm to about 300 μm (i.e. three times as great as for a rotational speed of 80 Hz). The variation in radius across the frame 8 can result in a deflection tilt of from about 0.5 mrad to about 5 mrad for a rotational speed of 80 Hz, or from about 1.5 mrad to about 15 mrad for a rotation speed of about 140 Hz.

Hence, in an embodiment, there is provided a system in which the variation in rotational speed of the frame 8 results in a deflection tilt which is reduced compared to the art. In an embodiment, the frame 8 is configured such that the angle α at which the flange 62 extends varies by upmost 1 mrad over the continuous range of rotational speeds. In an embodiment, the angle α varies by at most about 0.5 mrad, and optionally by at most about 0.1 mrad over the continuous range of rotational speeds.

In an embodiment, the continuous range of rotational speeds has a lower limit of 0. Hence, the angle α at which the flange 62 extends remains substantially constant from when the frame 8 is at rest to when the frame 8 rotates at the upper limit of the continuous range of rotational speeds. In an embodiment the continuous range of rotational speeds has an upper limit of at least 80 Hz, optionally at least 100 Hz, and optionally at least 140 Hz. The continuous range of rotational speeds is not particularly limited and may have an upper limit of 200 Hz or higher.

By the frame 8 not having a constant radius across its full height (in the Z direction), the frame 8 can have a relatively low weight. This can increase safety during an emergency stop of the frame 8 and means that the frame 8 should require a lesser amount of energy in order to speed up.

There are various ways of configuring the frame 8 such that the angle α at which the flange 62 extends is substantially constant over a continuous range of rotational speeds. As depicted in FIG. 6, the frame 8 may comprise a symmetric design in which the flange 62 undergoes a moment due to the shaft 70 on either side of the flange 62, wherein the two moments cancel each other out. In an embodiment, the angle α is substantially a right angle. In this case, the at least one lens 14, 18 may be positioned substantially in the plane of the flange 62. However, the flange 62 may extend relative to the axis 10 at an angle different from a right angle, for example at 85 degrees.

The deflection tilt of the flange 62 can be considered to be the result of a moment exerted on the flange 62 by the shaft 70. In general, the shaft 70 may have a smaller radius than the flange 62. As depicted in FIG. 6, as the shaft 70 expands, the lower section 63 of the shaft 70 may tilt about a hinge point 91. Of course, the hinge point 91 is in fact an annulus that extends around the axis 10, rather than being a single point. This results in the lower section 63 of the shaft 70 exerting a moment on the flange 64, thus causing the flange 64 to deflect, or tilt, as shown in the right hand section of FIG. 6.

In the symmetric design of FIG. 6, the moment exerted on the flange 62 by the upper section 61 of the shaft 70 substantially equals and opposes the moment exerted on the flange 62 by the lower section 63 of the shaft 70.

As a result, the shaft 70 exerts substantially no overall moment about an axis perpendicular to the axis 10 of rotation, on the flange 62. The deflection of flange 64 is shown in FIG. 6 merely for comparison with the non-deflected flange 62.

One way to help ensure that the upper section 61 and the lower section 63 of the shaft 70 exert substantially equal and opposing moments on the flange 62 is to have the cross-section of the upper section 61 correspond to the cross-section of the lower section 63 of the shaft 70. However, in an embodiment, a cross-section of the upper section 61 is different from a cross-section of the lower section 63 of the shaft. This is depicted, for example, in FIG. 6.

The moment exerted on the flange by the shaft 70 is given by the equation (1) below:

$${M}_{flange} = G \frac{Δ R}{Δ {z}_{Δ z = {t}_{f}}} \frac{Δ P}{2} {( {R}_{1}^{2} - {R}_{0}^{2} )}_{z = flange} z \qquad ( 1 )$$

G represents the shear modulus of the frame 8. ΔR represents the difference in radius of the frame 8 between different points along the vertical extent of the frame 8. In particular delta R equals ΔR_{z=i}−ΔR_{zΔi-1}. ΔP represents the “infinitely small” angle portion (in radians) of the frame 8. This allows the axisymmetric frame 8 to be considered as a two-dimensional problem. R₁ represents the outer radius of the shaft 70. R₀ represents the inner radius of the shaft 70. And, z represents the vertical coordinate along the axis 10 of rotation of the frame 8.

As depicted in FIG. 6, in an embodiment, the frame 8 comprises a hole 66 along the axis 10 of rotation. The hole 66 may be provided to allow for space for an actuator and/or a bearing, for example. However, the hole 66 may not be present in an embodiment. In this case, the actuator and/or bearing may be positioned outside of the frame 8.

FIG. 7 depicts schematically a frame 8 according to an embodiment of the invention. In each of FIGS. 7 to 12, the cross-sectional shape of one half of the frame 8 is depicted. In an embodiment the frame 8 has a shape that is substantially circularly symmetric about the axis 10.

In the embodiment depicted in FIG. 7, a section of the shaft 70 on one side, in the axial direction, of the flange 62 exerts substantially no moment on the flange 62. In this case, it is not necessary to balance the moment exerted on the flange 62 by a corresponding section of the shaft 70 on the opposite side of the flange 62 (in the axial direction). This is because the shaft 70 on one side of the flange 62 exerts substantially no moment on the flange 62.

One way to achieve the section of the shaft 70 exerting substantially no moment on the flange 62 is to choose the inner and outer radii of the flange 62 and the shaft 70 such that a product of the inner radius R₀ of the flange 62 and the outer radius R₁ of the flange 62 is substantially equal to the product of the inner radius R₂ of the shaft 70 and the outer radius R₃ of the shaft 70. It is desirable that R₀R₁=R₂R₃.

Exact equality of the products of the inner and outer radii of the flange 62 and the shaft 70 is not necessary. For example, the product R₀R₁ may differ from the product R₂R₃ by at most 20%, by at most 10%, or by at most 5%. In particular, if the product R₀R₁ is within 10% of the product R₂R₃, then there may be a significant reduction in deflection of the flange 62 such that the flange 62 extends at an angle α that is substantially constant as the rotational speed of the frame 8 varies for rotational speeds of up to about 140 Hz. Apart from the section of the shaft 70 that is adjacent to the flange 62, the remainder of the shaft 70 has an influence on the flange 62. Hence, for some parts of the shaft 70, there may be significant deviation from the equality R₀R₁=R₂R₃. However, the section of the shaft 70 adjacent to the flange 62 has the greatest influence on the flange 62.

In the case that there is no hole 66 in the frame 8, the equality R₀R₁=R₂R₃ is trivially satisfied. However, in this case (i.e. there is no hole 66 in the frame 8), it is desirable that the outer radius R₁ of the flange 62 is substantially equal to the outer radius R₃ of the shaft 70 such that the shaft 70 and the flange 62 expand by substantially the same amount such that there is substantially no overall deflection.

By providing compatible radii that satisfy R₀R₁=R₂R₃ (to within ±10%), similar expansion stresses are exerted at the cross-section where the flange 62 and the shaft 70 intersect. As such, there is loading equilibrium between the flange 62 and the shaft 70, thus resulting in substantially no deflection of the flange 62 as a result of the shaft 70.

FIGS. 8, 9 and 10 each depict an embodiment in which the flange 62 is at least partially decoupled from a moment exerted by the shaft 70. In an embodiment the flange 62 is connected to the shaft 70 by a connecter 80, 90 that is more flexible than the flange 62. For example, the connector 80, 90 may be thinner than the flange 62.

By at least partially decoupling the flange 62 from a moment exerted by the shaft 70, the deflection of the flange 62 as a result of the shaft 70 is decreased. This helps improve the accuracy of the focal plane of the lens 14, 18 held by the flange 62 during rotation of the frame 8.

FIG. 8 depicts an embodiment in which the flange 62 is connected to the shaft 70 by a connector 80, which takes the form of a membrane. When the shaft 70 variously tilts with respect to the axis 10 over the continuous range of rotational speeds, the connector 80 flexes such that the angle α at which the flange 62 extends is substantially constant.

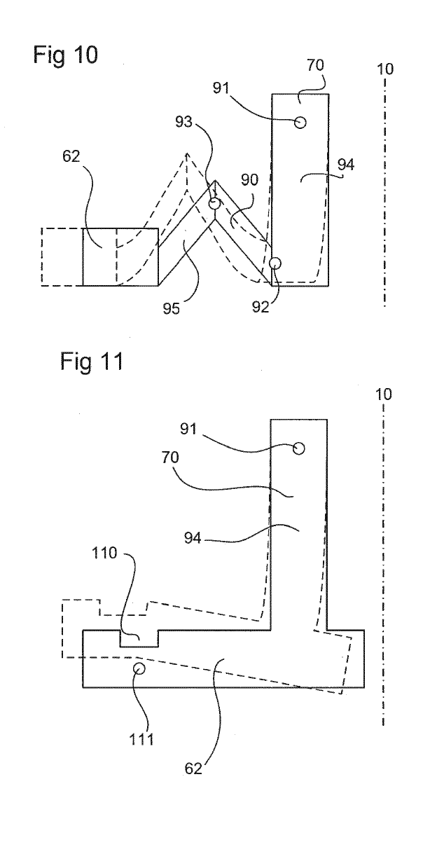

As the rotational speed of the frame 8 varies, the shaft 70 variously tilts with respect to the axis 10. As depicted in FIG. 8, the shaft 70 may tilt or deflect relative to the axis 10 of rotation about the hinge point 91. As mentioned above, the point 91 is in fact an annulus that extends around the axis 10 of rotation, rather than being a specific point. In FIG. 8 (as well as in FIGS. 9 to 10) the dashed lines represent the position of the frame 8 when the frame 8 is rotating. The angle of extension of the flange 62 is substantially constant for when the frame 8 is at rest (shown in black lines in FIGS. 8 to 10) and when the frame 8 is rotating (shown in dashed lines in FIGS. 8 to 10).

As depicted in FIG. 9, in an embodiment the connector comprises a shaft connection section 90 that extends from its connection (at hinge point 92) to the shaft 70 towards the middle 94, in the axial direction, of the shaft 70. In this embodiment, the flange 62 imposes a moment onto the shaft 70, the moment causing a deflection of the shaft 70 about the hinge point 91. An additional moment is imposed, having its center of rotation at the hinge point 92. As such, the frame 8 may be designed for reduced flange deflection. In an embodiment, the additional moment results in a deflection of the flange 62 that opposes and substantially equals the deflection about the hinge point 91.

As depicted in FIG. 9, in an embodiment the connector 90 is connected to the flange 62 at a position closer to the middle 94, in the axial direction, of the shaft 70 than a position 92 at which the connector 90 is connected to the shaft 70.

FIG. 10 depicts an embodiment in which the connector comprises a flange connection section 95 that extends from its connection to the flange 62 towards the middle 94 in the axial direction, of the shaft 70. The purpose of the flange connection section 95 is to reduce vertical displacement of the flange 62 during rotation of the frame 8. The flange 62 produces an additional moment, having its center of rotation at the hinge point 93 shown in FIG. 10.

In an embodiment, when the shaft 70 variously tilts with respect to the axis 10 over the continuous range of rotational speeds, the connector 80, 90 flexes such that the position, along the axis 10, of the flange 62 is substantially constant. This helps to reduce the effect of the rotation of the frame 8 on the vertical position of the flange 62, and therefore on the focusing provided by the lens 14, 18 held by the flange 62.

In an embodiment the flange connection section 95 and/or the connector 90 have a thickness that decreases gradually from radially inwards to radially outwards. In an embodiment the flange connection section 95 and the connector 90 have a saw-tooth shape as depicted in FIG. 10.

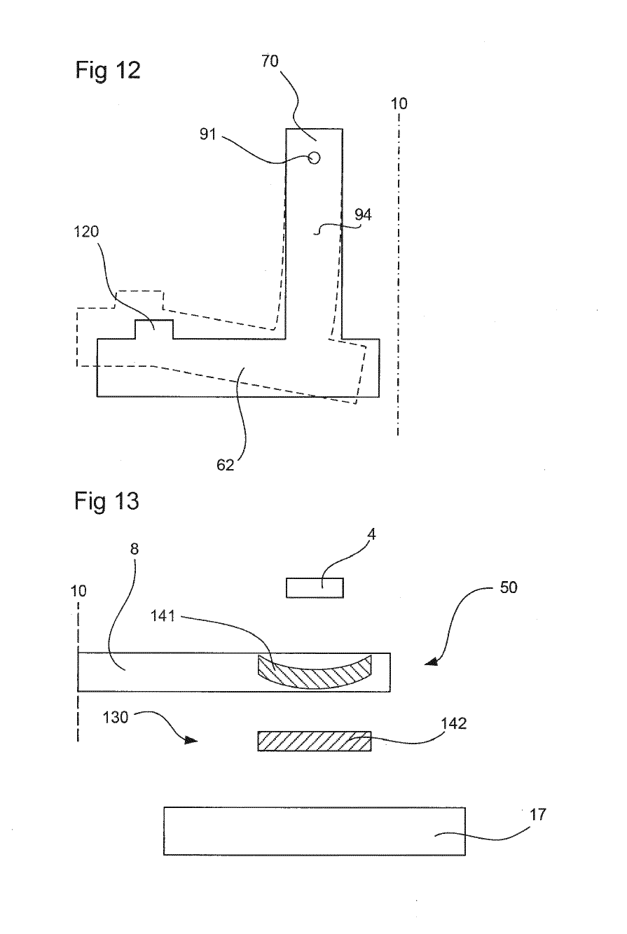

FIG. 11 depicts schematically a part of a frame 8 according to an embodiment of the present invention. In FIGS. 11 and 12, the solid black lines depict the position of the frame 8 at rest. The dashed lines represent the position of the frame 8 when the frame 8 is rotating about the axis 10.

When the frame 8 rotates, the flange 62 imposes a moment on the shaft 70. This causes the shaft 70 to tilt or deflect about the hinge point 91. In order to compensate for the resulting tilt or deflection on the flange 62, the flange 62 comprises a recess 110 on a surface of the flange 62 that faces the middle 94, in the axial direction, of the shaft 70.

In an embodiment, the recess 110 is a continuous recess that extends around the axis 10. However, for example, the recess 110 may comprise a series of recesses or depressions with discontinuities in between. In an embodiment the recess 110 is substantially circular and concentric with the frame 8.

The recess 110 partially separates the peripheral part of the flange 62 from the rest of the frame 8. The recess 110 introduces a non-symmetric suspension of the partially separated periphery of the flange 62. As a result, this peripheral part introduces a moment, which counteracts the original flange deflection. As depicted in FIG. 11, this moment results in the peripheral part of the flange 62 deflecting, or tilting, about the hinge point 111. As a result of the recess 110, the hinge point 111 of deflection is lower than would otherwise be the case.

FIG. 12 depicts an embodiment of the invention. As depicted in FIG. 12, the flange 62 comprises a protruding rim 120 on a surface of the flange 62 that faces the middle 94, in the axial direction, of the shaft 70. The protruding rim 120 imposes a moment onto the connection between the flange 62 and the shaft 70. One way to view this is to consider that the protruding rim 120 “wants to” expand more than the flange 62 allows it to.

By providing the protruding rim 120 that imposes a counter moment, the original flange deflection is at least partly counteracted by the presence of the protruding rim 120. By selecting the dimensions of the protruding rim 120, the original flange deflection can be counteracted such that the peripheral part of the flange 62 remains at the substantially same angle with respect to the axis 10 of rotation regardless of the rotational speed of the frame 8.

In an embodiment the lens 14, 18 held by the flange 62 is held at the peripheral part of the flange 62. As such, the lens 14, 18 remains at a substantially constant angle regardless of the speed of rotation of the frame 8.

In an embodiment the protruding rim 120 is a continuous protruding rim 120 that extends around the axis 10 of rotation of the frame 8. However, for example, in an embodiment the protruding rim 120 comprises discontinuities. The protruding rim 120 may comprise a plurality of protrusions, which may or may not be elongate. In an embodiment the protruding rim 120 is substantially circular and concentric with the frame 8.

If a rim or recess is positioned on the opposing surface of the flange 62, i.e. on the surface that faces away from the middle 94 of the shaft 70, then the rim or recess would result in an increased tilt or deflection of the flange 62.

In an embodiment, a monolithic component comprises the connector 80, 90, the flange 62 and the shaft 70. The frame 8 may be made from steel, for example. However, other suitable materials may also be used. In an embodiment, the frame 8 is an assembly of separate components corresponding to the shaft 70, the connector 80, 90 and the flange 62. In an embodiment the frame 8 is “solid”, which means that there is no hole 66 along the axis 10 of rotation. The frame 8 may be monolithic or assembled from various parts.

In an embodiment the frame 8 comprises a second flange 64. For example, in an embodiment, the flange 62 holds at least one field lens 14. Or, in an embodiment, the second flange 64 holds at least one imaging lens 18. In an embodiment the frame 8 is configured such that an angle β at which the second flange extends is substantially constant over a continuous range of rotational speeds.

An embodiment of the present invention makes it possible to at least partially compensate, or prevent, unwanted flange deflection. Flange deflection can otherwise result in misaligned optics in the apparatus 1. An embodiment of the present invention can be used to provide a frame 8 that can be used over a range of angular velocities, while retaining aligned optics. An embodiment of the present invention may not require any calibration or interface adjustment in order to make the optics aligned for a particular angle of velocity.

The frame 8 can be designed to be robust. The frame 8 can be manufactured relatively easily and inexpensively because, for example, it may not require moving parts and may not require large extra components that would increase the weight of the frame 8.

FIG. 13 depicts an embodiment of the present invention. FIG. 13 depicts a projection system 50 configured to project a radiation beam (or a plurality of radiation beams) onto a target (e.g., substrate 17). In an embodiment the projection system 50 comprises a frame 8 and a stationary part 130.

The frame 8 is configured to rotate about an axis 10 defining a tangential direction and a radial direction. For example, the radial direction extends radially outwards from the axis 10. The radial direction is perpendicular to the axis 10. The tangential direction is perpendicular to the radial direction and is in a plane perpendicular to the axis 10.

In an embodiment the frame 8 holds at least one lens 141 that moves with movement of the frame. The lens 141 is configured to focus the radiation beam in only the tangential or the radial direction.

In an embodiment the stationary part 130 comprises at least one substantially stationary lens 142. The substantially stationary lens 142 is configured to focus the radiation in only the other of the tangential or radial direction. The stationary part 130 is stationary with respect to the apparatus 1.

Hence, the functions of focusing the radiation beam in the tangential direction and the radial direction are divided between the lens 141 and the substantially stationary lens 142. This is different from other systems in which the lens held by the frame performs the functions of focusing the radiation beam in both the tangential direction and the radial direction.

According to an embodiment of the present invention, the substantially stationary lens 142 fully determines either the tangential position or the radial position of the radiation beam on the target. As a result, this aspect of the position of the radiation beam on the target is not affected by the position of the lens 141 held by the frame 8. Any movement of the lens 141 as the rotational speed of the frame 8 varies does not affect the aspect of the position of the radiation beam on the target that is fully determined by the substantially stationary lens 142.

In an embodiment the lens 141 is configured to focus the radiation beam in the tangential direction, and the substantially stationary lens 142 is configured to focus the radiation beam in the radial direction. The radial positioning of the radiation beam determines the position of lines drawn by the radiation beam on the target. In the system of interlaced printing mentioned above, the lines are placed to a very high accuracy, for example within 100 nm. By providing the substantially stationary lens 142 that focuses the radiation beam in the radial direction, the radial position of the radiation beam on the target is not substantially affected by the radial position of the lens 141 in the frame 8. Hence, the accuracy of positioning of the radiation beams on the target is improved. This makes interlaced printing more feasible.

By performing interlaced printing, it may not be necessary to provide the apparatus 1 with a pitch converter to narrow the pitch of the radiation beams focused by different lenses 141 in the frame 8. This is because in interlaced printing, the pitch can be relatively large, with subsequent patterns of lines interlacing in the gaps so as to form a continuous pattern on the target.

In an embodiment the lens 141 magnifies the radiation beam at a magnification, and the substantially stationary lens 142 magnifies the radiation beam at the same magnification. The magnification in the tangential and radial directions is affected by the position and the focal length of each of the lens 141 and the substantially stationary lens 142. In particular, the position of the lenses along the optical path affects the magnification. By selecting the positions and the focal lengths of the lenses, the magnification in the tangential and radial directions can be made substantially equal. However, in an embodiment, the magnification in the tangential direction is different from the magnification in the radial direction. This may be desirable, for example, if the self-emissive contrast device 4 comprises an elliptical source. In this case, by having a different magnification in the tangential and radial directions, the elliptical source can be compensated for.

In an embodiment the lens 141 is a field lens 141. In an embodiment the frame 8 holds at least one imaging lens 181 axially spaced from the field lens 141. The frame 8 may comprise two flanges 62, 64. The flange 62 may hold the field lens 141. The flange 64 may hold the imaging lens 181.

In an embodiment, the frame 8 holds at least 100 field lenses 141 and/or at least 100 imaging lenses 181. For example, there may be in the range of from about 120 to about 150 of each of the field lenses 141 and/or imaging lenses 181 held in the frame 8. As such, the width of each of the lenses 141, 181 is limited by the size of the frame 8.

The free working distance is determined by the numerical aperture (NA) and the width of the lens. A longer free working distance is desirable. The larger the width of a lens, the longer the free working distance. The substantially stationary lenses 142, 182 can be made to have a greater width than the lenses 141, 181, because the substantially stationary lenses 142, 182 do not have the same width restriction as the lenses 141, 181. Accordingly, the substantially stationary lenses 142, 182 can have a larger free working distance than the lenses 141, 181. An embodiment of the present invention allows the design area for the optics of the apparatus 1 to be enlarged. An apparatus 1 according to an embodiment of the present invention may not require a pitch converter to convert to a very small pitch.

In an embodiment the projection system 50 comprises at least two substantially stationary lenses 142, 182 axially spaced from each other. For example, there may be at least one substantially stationary lens 142 that pairs with the field lens 141 so as to together provide for field focusing in the tangential and radial directions. Another substantially stationary lens 182 may combine with the imaging lens 181 to focus in both the tangential and radial directions in the imaging plane.

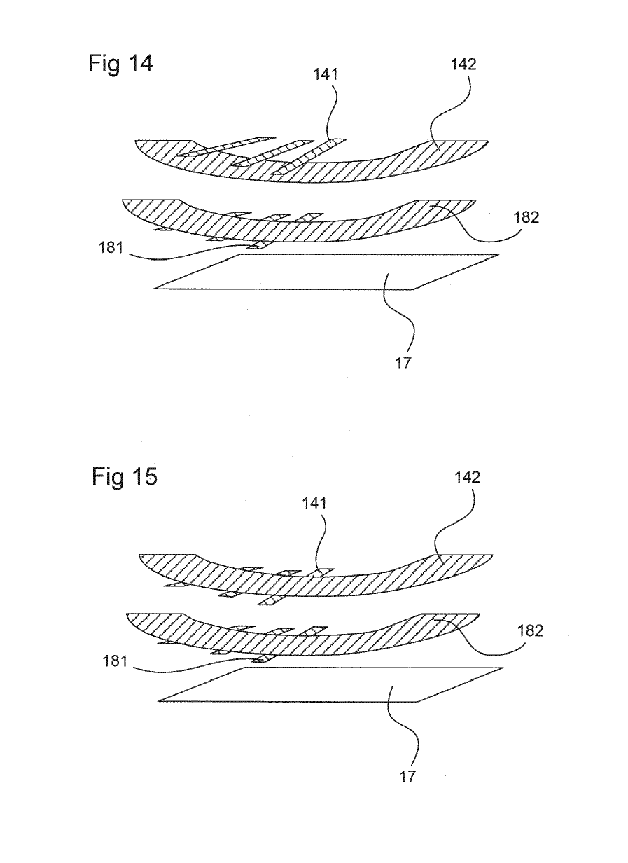

FIG. 14 depicts an embodiment of the invention. As depicted in FIG. 14, in an embodiment the at least two substantially stationary lenses 142, 182 are disposed between, in the axial direction, the at least one field lens 141 and the at least one imaging lens 181.

FIG. 15 depicts an embodiment in which each of the at least one field lens 141 and the at least one imaging lens 181 are disposed optically downstream, in the axial direction, of a respective one of the at least two substantially stationary lenses 142, 182.

The embodiments depicted in FIGS. 14 and 15 provide the greatest overall free working distance of the optical system. This is a particular advantage of the embodiments depicted in FIGS. 14 and 15.

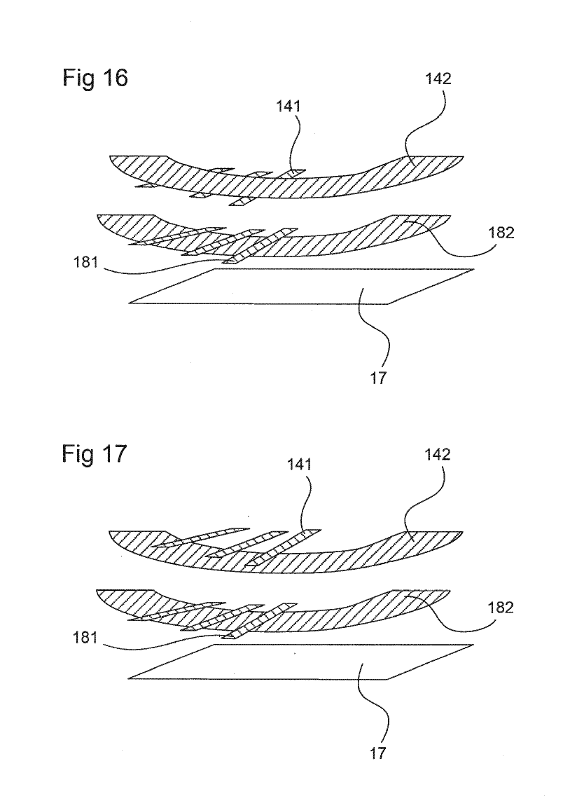

FIG. 16 depicts an embodiment in which the at least one field lens 141 and the at least one imaging lens 181 are disposed between, in the axial direction, the at least two substantially stationary lenses 142, 182.

By positioning both substantially stationary lenses 142, 182 outside of the frame 8, the projection system 50 of FIG. 16 is relatively easy to manufacture and maintain. Hence, the embodiment depicted in FIG. 16 is mechanically advantageous.

FIG. 17 depicts an embodiment in which each of the at least one field lens 141 and the at least one imaging lens 181 are disposed optically upstream, in the axial direction, of a respective one of the at least two substantially stationary lenses 142, 182.

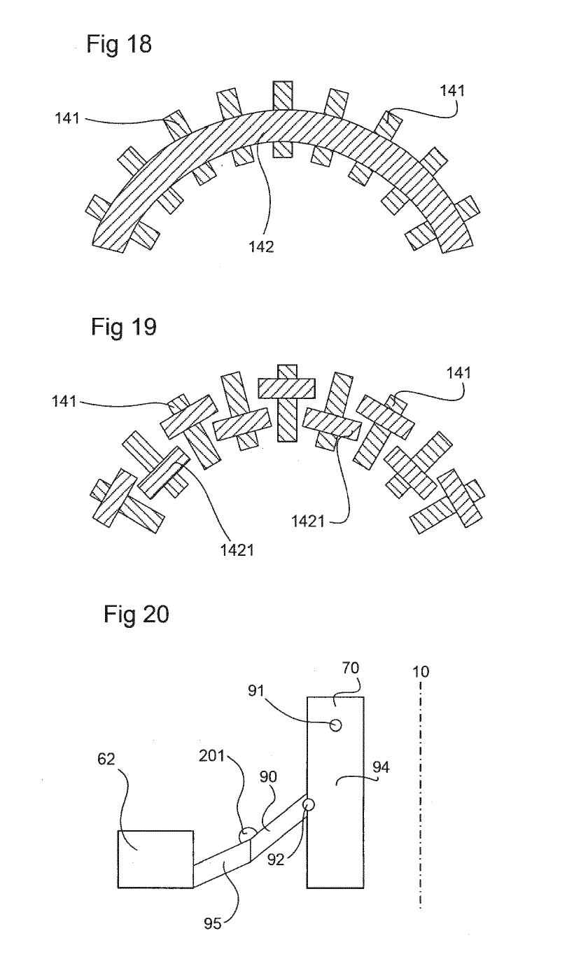

FIG. 18 depicts, in plan view, a substantially stationary lens 142 and a plurality of moving lenses 141. As depicted in FIG. 18, in an embodiment the substantially stationary lens 142 is made out of a single piece. In other words, the substantially stationary lens 142 may be monolithic. In an embodiment the substantially stationary lens 142 extends in the tangential direction of the frame 8. In an embodiment the substantially stationary lens 142 has a curved shape that corresponds to the tangential direction of the frame 8. This is depicted, for example, in FIG. 18.

However, this need not necessarily be the case. For example, as depicted in FIG. 19 in an embodiment the substantially stationary lens 142 is built up out of overlapping segments. In an embodiment the substantially stationary lens 142 comprises a plurality of overlapping, in the tangential direction, substantially stationary sub-lenses 1421. Here the term overlapping in the tangential direction means that when viewing the substantially stationary lens 142 along the radial direction, the substantially stationary lens appears to be continuous.

In an embodiment each of the plurality of substantially stationary sub-lenses 1421 is straight. However, in an embodiment at least one of the substantially stationary sub-lenses 1421 is curved. In particular the curve may follow the tangential direction of the frame 8.

FIG. 20 depicts an embodiment in which the connector comprises a flange connection section 95 that extends from its connection to the flange 62 towards the middle 94 in the axial direction, of the shaft 70. In an embodiment the connector 90 is connected to the shaft 70 at a position closer to the middle 94, in the axial direction, of the shaft 70 than a position 92 at which the connector 90 is connected to the flange 62.

The connector comprises a protrusion 201. In an embodiment the protrusion 201 is located at the ‘hinge’ point of the connector 90. The centrifugal force of the protrusion 201 helps ensure that the connector is straightened during rotation of the frame 8. This results in less deformation at the tip of the flange 62. The connector 90 may be formed of one piece of material, or by several parts attached to each other. For example in an embodiment the protrusion 201 is formed of a separate piece of material from the remainder of the connector 90. In an embodiment the protrusion is formed of a material that has a higher density than the rest of the connector 90.

In an embodiment the at least one lens 141, 181 comprises a cylinder lens. A cylinder lens is suitable for focusing the radiation beam in only one of the tangential or radial direction. Other types of lenses suitable for performing this function may be used.

In an embodiment the substantially stationary lens 142, 182 comprises a cylinder lens. In an embodiment, the lens 141, 181 extends in the radial direction. This is depicted in FIGS. 18 and 19, for example.

An embodiment of the present invention may allow the number of self-emissive contrast devices 4 to be reduced by, for example, almost 40% by arranging the self-emissive contrast devices 4 in a more optimized layout.

An embodiment of the present invention may allow for more accurate positioning of radiation beams because the positioning in the radial direction can be manipulated by the laser-firing timing (i.e. the timing at which the self-emissive contrast devices 4 are turned on and off), and the tangential positioning is fixed by substantially stationary optics which can be adjusted if needed.

An embodiment of the present invention enables interlaced printing. This results in less sensitivity to local disturbances due to the integrating nature with respect to disturbances.

In accordance with a device manufacturing method, a device, such as a display, integrated circuit or any other item may be manufactured from the substrate on which the pattern has been projected.

Although specific reference may be made in this text to the use of lithographic or exposure apparatus in the manufacture of ICs, it should be understood that the lithographic or exposure apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one of various types of optical components, including refractive, diffractive, reflective, magnetic, electromagnetic and electrostatic optical components or combinations thereof.

The descriptions above are intended to be illustrative, not limiting. Thus, it will be apparent to one skilled in the art that modifications may be made to the invention as described without departing from the scope of the claims set out below.

1. A rotatable frame, for use in a lithographic apparatus, configured to rotate about an axis, the rotatable frame comprising:
a shaft; and
a flange extending radially outwards at an angle relative to the axis and configured to hold a lens,
wherein the flange is positioned between an upper section and a lower section of the shaft, wherein the upper section and the lower section are configured such that, during rotation, a moment exerted on the flange by the upper section opposes and substantially equals a moment exerted on the flange by the lower section.

2. The frame of claim 1, wherein a cross-section of the upper section is different from a cross-section of the lower section.

3. The frame of claim 1, wherein a cross-section of the upper section corresponds to a cross-section of the lower section.

4. A rotatable frame, for use in a lithographic apparatus, configured to rotate about an axis, the rotatable frame comprising:
a shaft; and
a flange extending radially outwards at an angle relative to the axis and configured to hold a lens,
wherein, during rotation, a section of the shaft on one side, in the axial direction, of the flange exerts substantially no moment on the flange.

5. A rotatable frame, for use in a lithographic apparatus, configured to rotate about an axis, the rotatable frame comprising:
a shaft; and
a flange extending radially outwards at an angle relative to the axis and configured to hold a lens,
wherein the flange comprises a recess or a protruding rim on a surface of the flange that faces the middle, in the axial direction, of the shaft.

6. A rotatable frame, for use in a lithographic apparatus, configured to rotate about an axis, the rotatable frame comprising:
a shaft; and
a flange extending radially outwards at an angle relative to the axis and configured to hold a lens,
wherein the flange is connected to the shaft by a connector that is more flexible that the flange.

7. The frame of claim 6, wherein the connector is thinner than the flange.

8. The frame of claim 6, wherein the flange is connected to the shaft by the connector such that, during rotation, the connector flexes.

9. The frame of claim 6, configured such that, during rotation, the connector flexes such that a position, along the axis, of the flange is substantially constant over varying rotational speeds.

10. The frame of claim 6, wherein the connector comprises a shaft connection section that extends from its connection to the shaft towards a middle, in the axial direction, of the shaft.

11. The frame of claim 10, wherein the connector is connected to the flange at a position closer to the middle, in the axial direction, of the shaft than a position at which the connector is connected to the shaft.

12. The frame of claim 10, wherein the connector comprises a flange connection section that extends from its connection to the flange towards the middle, in the axial direction, of the shaft.

13. The frame of claim 6, wherein the flange has an inner edge a distance R₀ from the axis and an outer edge a distance R₁ from the axis, and a section of the shaft adjacent to the frame has an inner edge a distance R₂ from the axis and an outer edge a distance R₃ from the axis, wherein a product of R₀ and R₁ differs from a product of R₂ and R₃ by at most 10%.

14. The frame of claim 13, wherein the product of R₀ and R₁ is substantially equal to the product of R₂ and R₃.

15. The frame of claim 6, wherein the flange is at least partially decoupled from a moment exerted by the shaft.
